(19) United States
(12) Patent Application Publication
(10) Pub. No.: US 2026/0107776 A1
(43) Pub. Date: Apr. 16, 2026

(54) SEMICONDUCTOR DEVICE AND METHOD OF MANUFACTURING THE SAME

(71) Applicant: Renesas Electronics Corporation, Tokyo (JP)

(72) Inventor: Yusuke TANUMA, Tokyo (JP)

(21) Appl. No.: 19/304,893

(22) Filed: Aug. 20, 2025

(30) Foreign Application Priority Data
Oct. 10, 2024 (JP) 2024-178380

(51) Int. Cl. H01L 23/00; H01L 21/48; H01L 23/16; H01L 23/31; H01L 23/367; H01L 23/498; H01L 23/544

(52) U.S. Cl. CPC H10W 42/121; H10W 40/226; H10W 46/00; H10W 70/05; H10W 70/093; H10W 70/685; H10W 74/141; H10W 76/40; H10W 90/701; H10W 46/301; H10W 72/285; H10W 74/142; H10W 90/724

(57) ABSTRACT

To improve performance of a semiconductor device. A semiconductor device includes a wiring substrate, a semiconductor chip mounted on a first upper surface of the wiring substrate, an electronic component mounted on the first upper surface, and a stiffener ring fixed to the first upper surface. The stiffener ring includes a first portion arranged to continuously surround a periphery of the semiconductor chip in plan view and adhering to the first upper surface of the wiring substrate, and a second portion connected to the first portion and arranged at a position spaced away from the first upper surface of the wiring substrate in plan view. The second portion of the stiffener ring partially overlaps the electronic component.

### CROSS-REFERENCE TO RELATED APPLICATIONS

The disclosure of Japanese Patent Application No. 2024-178380 filed on Oct. 10, 2024 including the specification, drawings and abstract is incorporated herein by reference in its entirety.

### BACKGROUND

The present invention relates to a semiconductor device and a method of manufacturing the same.

There are disclosed techniques listed below.
[Patent Document 1] Japanese Unexamined Patent Application Publication No. 2003-51568
[Patent Document 2] Japanese Unexamined Patent Application Publication No. 2014-130961

In a semiconductor device in which a semiconductor chip is mounted on a wiring substrate, there is a technique of mounting a plate (stiffener ring) for reinforcing the wiring substrate on the wiring substrate (see, for example, Patent Document 1 and Patent Document 2).

### SUMMARY

A stiffener ring mounted on a wiring substrate is required to have a function of curbing warpage deformation of the wiring substrate. The stiffener ring is fixed onto the wiring substrate via, for example, an adhesive layer. In order to curb warpage deformation of the wiring substrate, it is necessary to prevent deformation of the stiffener ring itself.

On the other hand, an electronic component such as a chip capacitor may be mounted on a wiring substrate along with improvement in performance of the semiconductor device. In a case where an electronic component is mounted on a wiring substrate, a stiffener ring cannot adhere to the mounting region of the electronic component. In other words, in a case where the electronic component is mounted on the wiring substrate, the adhesion area between the wiring substrate and the stiffener ring is limited. Therefore, there is a need for a technique capable of preventing deformation of a stiffener ring itself with a limited adhesion area.

Other objects and novel features will become apparent from the description herein and the accompanying drawings.

A semiconductor device according to an embodiment includes: a wiring substrate; a semiconductor chip mounted on a first upper surface of the wiring substrate; an electronic component mounted on the first upper surface; and a stiffener ring fixed to the first upper surface. The stiffener ring includes: a first portion arranged to continuously surround a periphery of the semiconductor chip in plan view and adhering to the first upper surface of the wiring substrate; and a second portion connected to the first portion and arranged at a position spaced away from the first upper surface of the wiring substrate. The second portion of the stiffener ring partially overlaps the electronic component.

A method of manufacturing a semiconductor device according to another embodiment, includes: (a) preparing a wiring substrate including a first upper surface; (b) mounting a semiconductor chip on the first upper surface; (c) mounting an electronic component on the first upper surface; and (d) after the (b) and the (c), mounting a stiffener ring on the first upper surface. The stiffener ring mounted in the (d) has: a frame shape in plan view and includes a first portion adhering to the first upper surface in the (d); and a second portion connected to the first portion and arranged at a position spaced away from the first upper surface in the (d). In the (d), the stiffener ring is mounted on the first upper surface of each of the plurality of device regions such that the electronic component partially overlaps the second portion of the stiffener ring.

According to the above embodiment, the performance of the semiconductor device can be improved.

### BRIEF DESCRIPTION OF THE DRAWINGS

FIG. 1 is a top view of a semiconductor device according to an embodiment.

FIG. 2 is a bottom view of the semiconductor device illustrated in FIG. 1.

FIG. 3 is a cross-sectional view taken along line A-A in FIG. 1.

FIG. 4 is an enlarged cross-sectional view illustrating a part of an electronic component and a stiffener ring illustrated in FIG. 3 in an enlarged manner.

FIG. 5 is an enlarged cross-sectional view illustrating an example of a state in which a heat dissipation member is attached onto a semiconductor chip illustrated in FIG. 4.

FIG. 6 is an enlarged cross-sectional view illustrating a periphery of a part of a stiffener ring which is a modification example of the stiffener ring in FIG. 4.

FIG. 7 is an enlarged cross-sectional view schematically illustrating a state in which the stiffener ring illustrated in FIG. 6 is formed through half punching.

FIG. 8 is an enlarged cross-sectional view illustrating a periphery of a part of a stiffener ring according to another modification example of the stiffener ring in FIG. 4.

FIG. 9 is an enlarged cross-sectional view schematically illustrating a state in which the stiffener ring illustrated in FIG. 8 is formed through drawing.

FIG. 10 is an explanatory diagram illustrating an example of a flow of an assembly step of a semiconductor device according to an embodiment.

FIG. 11 is a plan view illustrating a modification example of a wiring substrate prepared in a wiring substrate preparing step illustrated in FIG. 10.

FIG. 12 is an enlarged plan view illustrating a state in which a positional relationship between an alignment mark and a stiffener ring is adjusted in an alignment step illustrated in FIG. 10.

### DETAILED DESCRIPTION

### Description of Description Format, Basic Term, and Usage in the Present Application

In the following embodiments, when necessary for the sake of convenience, the description thereof will be divided into a plurality of sections or embodiments, but unless otherwise specified, the sections or embodiments are not unrelated to each other, and one is in a relationship of some or all modification examples, details, supplementary description, and the like of the other. In the following embodiments, in a case of mentioning the number of elements or the like (including the number, a numerical value, an amount, a range, and the like), the number of elements is not limited to a specific number unless otherwise specified or obviously limited to the specific number in principle, and the number of elements may be greater than or equal to or less than the specific number. In the following embodiments, it goes without saying that the constituents (including element steps and the like) are not necessarily essential unless otherwise specified or considered to be obviously essential in principle. Similarly, in the following embodiments, references to the shapes, positional relationships, etc. of constituents are intended to include those that are substantially similar or approximate thereto, unless explicitly stated otherwise or unless it is clearly not so by principle. The same applies to the above-mentioned numerical values and ranges.

Similarly, in the description of the embodiments and the like, even if a material, a composition, and the like are described as “X including A” and the like, those including elements other than A are not excluded unless otherwise specified or clearly indicated from the context. For example, the component means “X containing A as a main component” or the like. For example, the term “silicon member” or the like is not limited to pure silicon, and it goes without saying that the silicon member includes a member containing a SiGe (silicon-germanium) alloy, other multicomponent alloys containing silicon as a main component, other additives, and the like. In addition, gold plating, a Cu layer, nickel plating, and the like include not only pure materials but also members containing gold, Cu, nickel, and the like as main components, respectively, unless otherwise specified.

In the drawings of the embodiments, the same or similar parts are denoted by the same or similar symbols or reference numerals, and the description will not be repeated in principle.

In the accompanying drawings, hatching or the like may be omitted even in a cross section. In this regard, in a case where it is obvious from the description and the like, the outline of the background may be omitted even in the case of a hole that is closed in a planar manner. Even for a portion other than a cross section, hatching or a dot pattern may be added in order to clearly indicate that it is not a void or clearly indicate a boundary of a region.

### Semiconductor Device

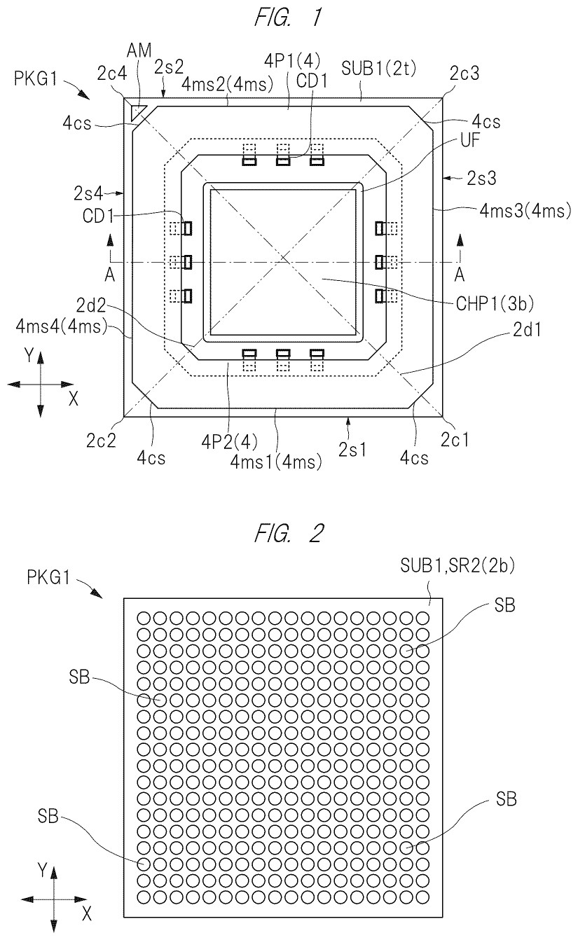

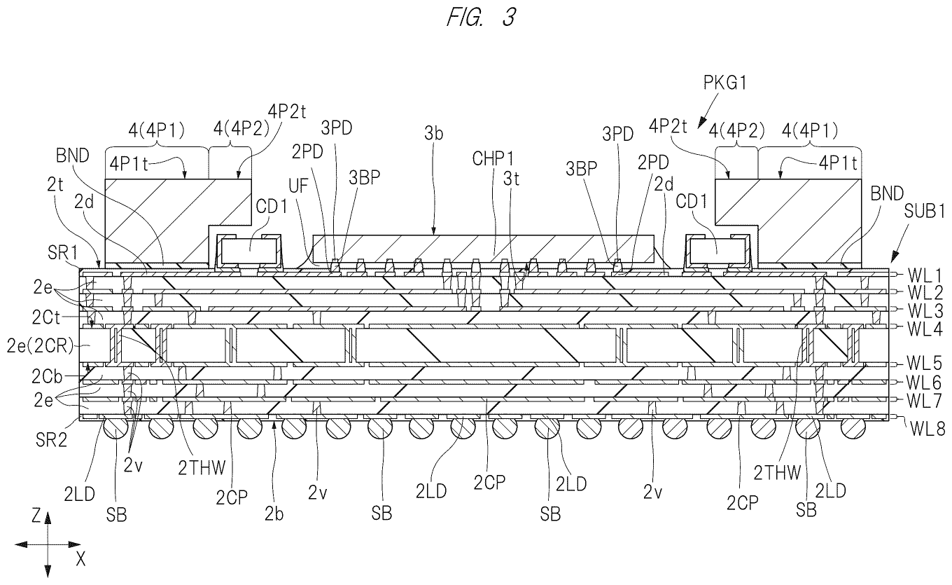

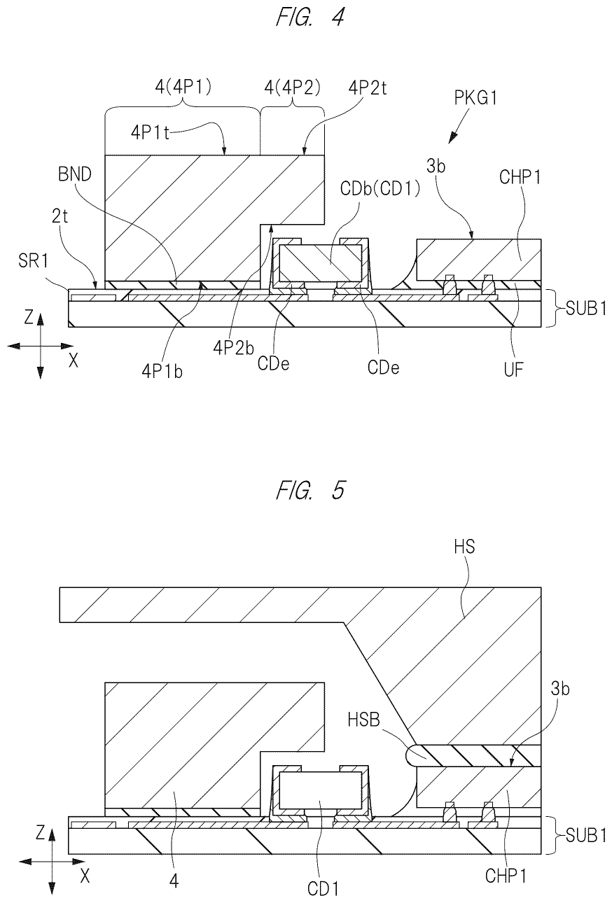

FIG. 1 is a top view of a semiconductor device according to an embodiment. FIG. 2 is a bottom view of the semiconductor device illustrated in FIG. 1. FIG. 3 is a cross-sectional view taken along line A-A in FIG. 1. In FIG. 1, the outline of a semiconductor chip CHP1 covered with a stiffener ring 4 is indicated by a dotted line. FIG. 4 is an enlarged cross-sectional view illustrating a part of an electronic component and a stiffener ring illustrated in FIG. 3 in an enlarged manner. FIG. 5 is an enlarged cross-sectional view illustrating an example of a state in which a heat dissipation member is attached onto a semiconductor chip illustrated in FIG. 4.

FIGS. 1 to 3 illustrate one of an X direction (see FIGS. 1 to 3), a Y direction (see FIGS. 1 and 2), and a Z direction (see FIG. 3). The Y direction is a side intersecting the X direction, and the X direction and the Y direction are orthogonal to each other in the following description. The Z direction is a direction orthogonal to each of the X direction and the Y direction. In other words, the Z direction is a normal direction with respect to the X-Y plane including the X direction and the Y direction. In the following description, “thickness” basically indicates a length in the Z direction. In the following description, “plan view” basically indicates a plan view in which the X-Y plane is viewed.

A semiconductor device PKG1 of the present embodiment includes a wiring substrate SUB1 and a semiconductor chip CHP1 (see FIG. 3) mounted on the wiring substrate SUB1. The semiconductor device PKG1 includes a stiffener ring 4 arranged to continuously surround the periphery of the semiconductor chip CHP1 in plan view. The semiconductor device PKG1 includes an electronic component CD1 mounted on the wiring substrate SUB1.

The wiring substrate SUB1 is mainly made of a so-called organic material in which glass fibers are impregnated with an epoxy-based resin. The semiconductor chip CHP1 is mainly made of, for example, silicon. That is, in the present embodiment, the linear expansion coefficient (thermal expansion coefficient) of the wiring substrate SUB1 and the linear expansion coefficient (thermal expansion coefficient) of the semiconductor chip CHP1 are different from each other. Here, in recent years, the planar size of the wiring substrate SUB1 to be used has been larger than before along with the high functionality of a semiconductor device. As illustrated in FIG. 1, in a case where the semiconductor chip CHP1 is disposed to overlap the center of the wiring substrate SUB1 (the intersection of a diagonal line 2d1 and a diagonal line 2d2 illustrated in FIG. 1), the warpage deformation of the wiring substrate SUB1 due to the difference between the linear expansion coefficients becomes large in the peripheral edge portion (in particular, the corner portion) of the wiring substrate SUB1.

Therefore, in the present embodiment, the stiffener ring 4 is mounted on the wiring substrate SUB1 in order to curb the warpage deformation of the wiring substrate SUB1.

Hereinafter, details of the semiconductor device PKG1 will be described.

As illustrated in FIG. 3, the wiring substrate SUB1 included in the semiconductor device PKG1 includes an upper surface 2t that is a chip mounting surface and a lower surface 2b opposite the upper surface 2t. The lower surface 2b functions as a mounting surface of the semiconductor device PKG1.

As illustrated in FIG. 1, the upper surface 2t of the wiring substrate SUB1 includes a side 2s1, a side 2s2 opposite the side 2s1, a side 2s3 intersecting the side 2s1 and the side 2s2, and a side 2s4 opposite the side 2s3. The upper surface 2t includes a corner 2c1 that is an intersection between the side 2s1 and the side 2s3, a corner 2c2 that is an intersection between the side 2s1 and the side 2s4, a corner 2c3 that is an intersection between the side 2s2 and the side 2s3, and a corner 2c4 that is an intersection between the side 2s2 and the side 2s4.

Although a virtual line is used instead of a visible line, since the upper surface 2t is a quadrangle, two diagonal lines can be drawn. That is, a diagonal line 2d1 connecting the intersection (corner 2c1) between the side 2s1 and the side 2s3 and the intersection (corner 2c4) between the side 2s2 and the side 2s4 can be drawn on the upper surface 2t. A diagonal line 2d2 connecting the intersection (corner 2c2) between the side 2s1 and the side 2s4 and the intersection (corner 2c3) between the side 2s2 and the side 2s3 can be drawn on the upper surface 2t. In the example illustrated in FIG. 1, the side 2s1 and the side 2s2 are sides extending in the X direction, and the side 2s3 and the side 2s4 are sides extending in the Y direction.

The wiring substrate SUB1 included in the semiconductor device PKG1 includes an internal interface terminal (pad 2PD) exposed from an insulating film SR1 on the upper surface 2t and an external interface terminal (land 2LD) exposed from an insulating film SR2 on the lower surface 2b which is a mounting surface.

The wiring substrate SUB1 includes a plurality of wiring layers that electrically connects the internal interface terminal and the external interface terminal. In the example illustrated in FIG. 3, the wiring substrate SUB1 is a wiring substrate having an eight-layer structure including a wiring layer WL1, a wiring layer WL2, a wiring layer WL3, a wiring layer WL4, a wiring layer WL5, a wiring layer WL6, a wiring layer WL7, and a wiring layer WL8. However, the number of wiring layers of the wiring substrate SUB1 is not limited to eight, and may be seven or less, or nine or more.

Each wiring layer is located between the upper surface 2t and the lower surface 2b. Each wiring layer has a conductor pattern such as a wiring that is a path for supplying an electric signal or power. The wiring layers are electrically connected to each other via a via wiring 2v or a through-hole wiring 2THW which is an interlayer conductive path penetrating an insulating layer 2e. The insulating layer 2e is arranged between the wiring layers. The plurality of insulating layers 2e arranged between the respective wiring layers includes a core insulating layer (an insulating layer, a core material, or a core insulating layer) 2CR arranged between the upper surface 2t and the lower surface 2b. The core insulating layer 2CR is a core member for securing rigidity of the wiring substrate SUB1, and is made of, for example, a prepreg in which glass fiber is impregnated with a resin.

Among the plurality of wiring layers, the wiring layer WL1 arranged closest to the upper surface 2t is covered with an insulating film SR1. An opening is provided in the insulating film SR1, and each of the plurality of pads 2PD provided in the wiring layer WL1 is exposed from the insulating film SR1 at the opening.

Among the plurality of wiring layers, the plurality of lands 2LD is provided in the wiring layer WL8 arranged at a position closest to the lower surface 2b side of the wiring substrate SUB1. The wiring layer WL8 is covered with an insulating film SR2. Each of the insulating film SR1 and the insulating film SR2 is a solder resist film made of an organic material capable of curbing solder wetting and spreading. The plurality of pads 2PD provided in the wiring layer WL1 and the plurality of lands 2LD provided in the wiring layer WL8 are each electrically connected via conductor patterns (wirings 2d or large-area conductor patterns 2CP) formed in each wiring layer included in the wiring substrate SUB1, the via wirings 2v, and the through-hole wirings 2THW.

Each of the wiring 2d, the pad 2PD, the via wiring 2v, a via land (not illustrated), a through-hole land (not illustrated), the through-hole wiring 2THW, the land 2LD, and the conductor pattern 2CP is made of, for example, copper or a metal material containing copper as a main component.

The wiring substrate SUB1 is formed, for example, by laminating a plurality of wiring layers on an upper surface 2Ct and a lower surface 2Cb of the core insulating layer (an insulating layer, a core material, or a core insulating layer) 2CR by using a build-up method. The wiring layer WL4 on the upper surface 2Ct side of the core insulating layer 2CR and the wiring layer WL5 on the lower surface 2Cb side are electrically connected via a plurality of through-hole wirings 2THW embedded in a plurality of through-holes provided to penetrate from one of the upper surface 2Ct and the lower surface 2Cb to the other.

In the example illustrated in FIG. 3, a plurality of solder balls (a solder material, an external terminal, an electrode, or an external electrode) SB is formed on the lower surface 2b of the wiring substrate SUB1. Specifically, the solder balls SB are respectively connected to the plurality of lands 2LD of the wiring substrate SUB1. The solder balls SB are conductive members that electrically connect a plurality of terminals (not illustrated) on a motherboard side to the plurality of lands 2LD in a case where the semiconductor device PKG1 is mounted on the motherboard (not illustrated). The solder ball SB is, for example, an Sn—Pb solder material containing lead (Pb) or a solder material made of so-called lead-free solder substantially containing no Pb. Examples of the lead-free solder include only tin (Sn), tin-bismuth (Sn—Bi), tin-copper-silver (Sn—Cu—Ag), and tin-copper (Sn—Cu). Here, the lead-free solder indicates that the content of lead (Pb) is 0.1 wt % or less, and this content is defined as a standard of the Restriction of Hazardous Substances (RoHS) Directive.

As illustrated in FIG. 2, a plurality of solder balls SB is arranged in a matrix (an array shape or a matrix shape). Although not illustrated in FIG. 2, a plurality of lands 2LD (see FIG. 3) to which the plurality of solder balls SB is bonded is also arranged in a matrix shape. As described above, the semiconductor device in which the plurality of external terminals (the solder balls SB and the lands 2LD) are arranged in a matrix shape on the mounting surface side of the wiring substrate SUB1 will be referred to as an area array type semiconductor device. The area array type semiconductor device is preferable in that the mounting surface (lower surface 2b) side of the wiring substrate SUB1 can be effectively used as an arrangement space for external terminals, and thus an increase in the mounting area of the semiconductor device can be suppressed even if the number of external terminals increases. That is, it is possible to mount a semiconductor device in which the number of external terminals increases with higher functionality and higher integration in a space-saving manner.

The semiconductor device PKG1 includes the semiconductor chip CHP1 mounted on the wiring substrate SUB1. As illustrated in FIG. 3, the semiconductor chips CHP1 includes a front surface (a main surface or an upper surface) 3t in which a plurality of projecting electrodes 3BP is disposed, and a back surface (a main surface or a lower surface) 3b on a side opposite the front surface 3t.

As illustrated in FIG. 1, the semiconductor chip CHP1 has a quadrangular outer shape having a smaller plane area than that of the wiring substrate SUB1 in plan view. In the example illustrated in FIG. 1, the semiconductor chip CHP1 is mounted on a central portion of the upper surface 2t of the wiring substrate SUB1. The four sides of the semiconductor chip CHP1 respectively extend along the four sides (the side 2s1, the side 2s2, the side 2s3, and the side 2s4) of the upper surface 2t of the wiring substrate SUB1.

As illustrated in FIG. 3, a plurality of electrodes (pads, electrode pads, or bonding pads) 3PD is formed on the front surface 3t side of the semiconductor chip CHP1. The front surface 3t is an outermost surface of the semiconductor chip CHP1. The front surface 3t includes an upper surface of a passivation film (not illustrated) and an upper surface of the electrode 3PD exposed from the passivation film. Since the plurality of projecting electrodes 3BP is formed on the electrodes 3PD, it can be expressed that the plurality of projecting electrodes 3BP is formed on the front surface 3t.

In the example illustrated in FIG. 3, the semiconductor chip CHP1 is mounted on the wiring substrate SUB1 in a state in which the front surface 3t faces the upper surface 2t of the wiring substrate SUB1. Such a mounting method is called a face-down mounting method or a flip-chip connection method.

Although not illustrated, a plurality of semiconductor elements (circuit elements) is formed on the main surface (specifically, a semiconductor element formation region provided on an element formation surface of a semiconductor substrate which is a base material of the semiconductor chip CHP1) of the semiconductor chip CHP1. The plurality of electrodes 3PD is respectively electrically connected to the plurality of semiconductor elements via wirings (not illustrated) formed in a wiring layer arranged inside the semiconductor chip CHP1 (specifically, between the front surface 3t and the semiconductor element formation region (not illustrated)).

The semiconductor chip CHP1 (specifically, the semiconductor substrate of the semiconductor chip CHP1) is made of, for example, silicon (Si). An insulating film (a passivation film (not illustrated)) covering the semiconductor substrate and the wirings of the semiconductor chip CHP1 is formed on the front surface 3t, and a part of each of the plurality of electrodes 3PD is exposed from the passivation film in an opening formed in the passivation film. Each of the plurality of electrodes 3PD is made of metal, and is made of, for example, aluminum (Al) in the present embodiment.

As illustrated in FIG. 3, the plurality of electrodes 3PD is respectively connected to the projecting electrodes 3BP, and the plurality of electrodes 3PD of the semiconductor chip CHP1 and the plurality of pads 2PD of the wiring substrate SUB1 are electrically connected to each other via the plurality of projecting electrodes 3BP. The projecting electrode (bump electrode) 3BP is a metal member (conductive member) formed to project on the front surface 3t of the semiconductor chip CHP1. In the present embodiment, the projecting electrode 3BP has a structure in which a columnar electrode (so-called copper pillar electrode) made of, for example, copper is formed on the electrode 3PD, and a solder material is laminated on the tip of the columnar electrode. As the solder material laminated on the tip of the columnar electrode, a lead-containing solder material or a lead-free solder may be used similarly to the solder ball SB described above.

In a case where the semiconductor chip CHP1 is mounted on the wiring substrate SUB1, a bonding material (for example, a base metal film or a solder paste) having good bondability with solder is formed in advance on the plurality of pads 2PD. Performing heat treatment (reflow treatment) in a state in which the solder material on the tip of the columnar electrode and the bonding material on the pad 2PD are in contact with each other allows the solder to be integrated to form the projecting electrode 3BP. As a modification example of the present embodiment, a so-called solder bump in which a micro-solder ball is formed on a columnar electrode made of nickel (Ni) or on the electrode 3PD via a base metal film may be used as the projecting electrode 3BP.

As illustrated in FIG. 3, an underfill resin (insulating resin) UF is disposed between the semiconductor chip CHP1 and the wiring substrate SUB1. The underfill resin UF is arranged to close a space between the front surface 3t of the semiconductor chip CHP1 and the upper surface 2t of the wiring substrate SUB1. Each of the plurality of projecting electrodes 3BP is sealed with the underfill resin UF. The underfill resin UF is made of an insulating (non-conductive) material (for example, a resin material), and is arranged to seal electrical connection portions between the semiconductor chip CHP1 and the wiring substrate SUB1 (bonding portions of the plurality of projecting electrodes 3BP). As described above, covering the bonding portions between the plurality of projecting electrodes 3BP and the plurality of pads 2PD with the underfill resin UF can alleviate the stress generated at the electrical connection portions between the semiconductor chip CHP1 and the wiring substrate SUB1. The stress generated at the bonding portions between the plurality of electrodes 3PD and the plurality of projecting electrodes 3BP of the semiconductor chip CHP1 can also be alleviated. Further, it is possible to protect the main surface of the semiconductor chip CHP1 on which the semiconductor element (circuit element) is formed.

As illustrated in FIG. 3, the stiffener ring 4 is adhesively fixed onto the wiring substrate SUB1 via an adhesive layer BND (see FIG. 3). As illustrated in FIG. 1, the stiffener ring 4 is an annular member arranged to continuously surround the periphery of the semiconductor chip CHP1 in plan view. The stiffener ring 4 is made of metal such as copper (Cu). In a case where the copper stiffener ring 4 is used, a metal film such as nickel may be formed on surfaces (for example, an upper surface, a lower surface, and an inner surface) of the stiffener ring 4 from the viewpoint of preventing oxidation of the surfaces.

One object of mounting the stiffener ring 4 on the wiring substrate SUB1 is to curb warpage deformation of the wiring substrate SUB1. The warpage deformation of the wiring substrate SUB1 occurs due to a difference between the linear expansion coefficient (thermal expansion coefficient) of the wiring substrate SUB1 and the linear expansion coefficient (thermal expansion coefficient) of the semiconductor chip CHP1. In the peripheral edge portion (in particular, the corner portion) of the wiring substrate SUB1, the warpage deformation becomes the largest. Therefore, the stiffener ring 4 is arranged along the peripheral edge portion of the upper surface 2t.

In order to curb the warpage deformation of the wiring substrate SUB1 by using the stiffener ring 4, a high adhesion strength between the stiffener ring 4 and the wiring substrate SUB1 is required. In order to curb the warpage deformation of the wiring substrate SUB1 by using the stiffener ring 4, the stiffener ring 4 is required to have a high rigidity so that the stiffener ring 4 itself is not deformed due to an external force.

Incidentally, in a BGA type semiconductor device, there is a cover member called a lid as a member disposed to cover a semiconductor chip. Since the lid is disposed on a wiring substrate to cover the semiconductor chip, the lid adheres not only to the wiring substrate but also to the semiconductor chip. Therefore, not only the strength of an adhesive layer that causes the lid and the wiring substrate to adhere to each other but also the strength of fixing the lid to the wiring substrate via the semiconductor chip contributes to the adhesion strength between the lid and the wiring substrate.

On the other hand, since the stiffener ring 4 of the present embodiment is an annular member, the stiffener ring 4 and the semiconductor chip CHP1 are separated from each other. That is, the stiffener ring 4 is disposed on the wiring substrate SUB1 so as not to cover the semiconductor chip CHP1. In this case, the fixing strength between the semiconductor chip CHP1 and the wiring substrate SUB1 does not contribute to the adhesion strength between the stiffener ring 4 and the wiring substrate SUB1. From the viewpoint of “rigidity” described above, the stiffener ring 4 has lower rigidity than that of the lid. This is because a portion of the stiffener ring 4 overlapping the semiconductor chip CHP1 is open.

As described above, since the stiffener ring 4 is an annular member, the back surface 3b of the semiconductor chip CHP1 is exposed even after the stiffener ring 4 is mounted on the wiring substrate SUB1. In this case, for example, a heat sink for heat dissipation having a size larger than the size of the upper surface 2t of the wiring substrate SUB1 can be brought into direct contact with the back surface 3b of the semiconductor chip CHP1. This point is that the stiffener ring 4 is superior to the lid.

As illustrated in FIGS. 1 and 3, the semiconductor device PKG1 includes the electronic component CD1 mounted on the upper surface 2t of the wiring substrate SUB1. In the example illustrated in FIG. 1, a plurality of electronic components CD1 is mounted between the semiconductor chip CHP1 and the stiffener ring 4.

Each of the plurality of electronic components CD1 is a surface mount chip component, and is mounted on the wiring substrate SUB1 via solder. Each of the plurality of electronic components CD1 includes, for example, a capacitor, an inductor, or a resistor. In recent years, a plurality of electronic components CD1 has been mounted on the upper surface 2t of the wiring substrate SUB1 separately from the semiconductor chip CHP1 in some cases along with the high functionality of semiconductor devices. Each of the plurality of electronic components CD1 is disposed to protrude from the upper surface 2t of the wiring substrate SUB1.

As illustrated in FIG. 4, the electronic component CD1 includes a plurality of electrodes CDe (two electrodes in FIG. 4) and a main body portion CDb connected to each of the plurality of electrodes CDe. In the main body portion CDb, for example, a capacitor element, an inductor element, or a resistor element is formed. As described above, since the electronic component CD1 is a surface mount chip component, both the main body portion CDb and the plurality of electrodes CDe are arranged on the upper surface 2t of the wiring substrate SUB1.

In a case where the electronic component CD1 is mounted on the wiring substrate SUB1, a part of the upper surface 2t of the wiring substrate SUB1 is occupied by the electronic component CD1, so that the adhesion area between the stiffener ring 4 and the wiring substrate SUB1 is limited. For example, in a case where the shape of the stiffener ring 4 is a simple frame shape (for example, only an adherend portion 4P1 illustrated in FIG. 1), the volume of the stiffener ring 4 is restricted due to mounting of the electronic component CD1.

In order to improve the rigidity of the stiffener ring 4, it is conceivable to increase the thickness of the stiffener ring 4. However, in a case where the thickness of the stiffener ring 4 is extremely increased, for example, as exemplified in FIG. 5, the accessibility in a case where a heat dissipation member (a heat spreader or a heat sink) HS or the like is mounted on the back surface 3b of the semiconductor chip CHP1 via a heat dissipation adhesive layer HSB deteriorates. This is because the heat dissipation member HS has improved heat dissipation characteristics in proportion to the heat dissipation area, and thus the heat dissipation member HS is preferably provided to cover the stiffener ring 4. From the viewpoint of ensuring this accessibility, it is difficult to extremely increase the thickness of the stiffener ring 4.

In order to increase the width of the adherend portion 4P1 of the stiffener ring 4, a method of increasing the area of the upper surface 2t of the wiring substrate SUB1 is also conceivable. However, in this case, since the size of the semiconductor device PKG1 increases, it is not possible to meet the demand for miniaturization of the semiconductor device. When the area of the upper surface 2t increases, the stress generated in the peripheral edge portion of the wiring substrate SUB1 increases, which results in promoting the warpage deformation. Thus, in the case of the semiconductor device PKG1 in which the electronic component CD1 is mounted on the upper surface 2t of the wiring substrate SUB1 as in the present embodiment, it is necessary to improve the rigidity of the stiffener ring 4 under the constraint that the thickness of the stiffener ring 4 or the area of the upper surface 2t is not extremely increased.

Based on the above content, the inventor of the present application has examined a technique capable of improving the rigidity of the stiffener ring 4 by devising a shape of the stiffener ring 4. Details thereof will be described below.

### Details of Stiffener Ring

As illustrated in FIGS. 1, 3, and 4, the stiffener ring 4 includes the adherend portion 4P1 and a separation portion 4P2. As illustrated in FIG. 1, in plan view, the adherend portion 4P1 is arranged to continuously surround the periphery of the semiconductor chip CHP1. In the example illustrated in FIG. 1, the separation portion 4P2 is arranged between the adherend portion 4P1 and the semiconductor chip CHP1 to continuously surround the semiconductor chip CHP1. As illustrated in FIG. 3, the adherend portion 4P1 adheres to the upper surface 2t of the wiring substrate. The separation portion 4P2 is connected to the adherend portion 4P1 and is arranged at a position spaced away from the upper surface 2t of the wiring substrate SUB1. At least a part of the electronic component CD1 is covered with the separation portion 4P2 of the stiffener ring 4. That is, the electronic component CD1 partially overlaps the separation portion 4P2 of the stiffener ring 4.

Specifically, as illustrated in FIG. 4, the adherend portion 4P1 of the stiffener ring 4 has a lower surface 4P1b facing the upper surface 2t of the wiring substrate and an upper surface 4P1t located on the opposite side to the lower surface 4P1b. The separation portion 4P2 of the stiffener ring 4 has a lower surface 4P2b facing the upper surface 2t of the wiring substrate and an upper surface 4P2t located on the opposite side to the lower surface 4P2b.

The adherend portion 4P1 is a portion of the stiffener ring 4 having a lower surface 4P1b, that is, a portion facing the upper surface 2t of the wiring substrate SUB1 via the adhesive layer BND. On the other hand, the separation portion 4P2 is a portion having the lower surface 4P2b arranged at a position higher than the lower surface 4P1b with the upper surface 2t of the wiring substrate SUB1 as a reference surface. Since the lower surface 4P2b of the separation portion 4P2 is arranged at a higher position, a space is generated between the separation portion 4P2 and the wiring substrate SUB1. In the present embodiment, at least a part of the electronic component CD1 is arranged in the space between the separation portion 4P2 and the wiring substrate SUB1. As a result, even in a case where the width (the length in the X direction) of the stiffener ring 4 is increased, it is possible to prevent the area of the upper surface 2t of the wiring substrate SUB1 from increasing.

In the case of the semiconductor device PKG1 according to the present embodiment, since the electronic component CD1 is mounted on the wiring substrate SUB1, the width of the adherend portion 4P1 of the stiffener ring 4 is limited. On the other hand, the separation portion 4P2 of the stiffener ring 4 is arranged at a position overlapping the electronic component CD1. Therefore, there is no restriction on the length of the separation portion 4P2 in the width direction (X direction illustrated in FIG. 3) due to the mounting of the electronic component CD1.

From the viewpoint of the rigidity of the stiffener ring 4, the following description will be made. That is, since the separation portion 4P2 is connected to the adherend portion 4P1, the adherend portion 4P1 and the separation portion 4P2 behave as rigid bodies. Therefore, the rigidity of the stiffener ring 4 can be improved by connecting the adherend portion 4P1 and the separation portion 4P2. As described above, it is preferable to improve the rigidity of the stiffener ring 4 from the viewpoint of curbing the warpage deformation of the wiring substrate SUB1. According to the present embodiment, since the rigidity of the stiffener ring 4 can be improved, warpage deformation of the wiring substrate SUB1 can be curbed.

Incidentally, although not illustrated, as a modification example related to FIG. 1, there is a case where the separation portion 4P2 is not provided to continuously surround the semiconductor chip CHP1 (for example, in a case where the separation portion 4P2 is connected to a part of the frame-shaped adherend portion 4P1). Even in this case, the rigidity of the stiffener ring 4 can be improved. However, as illustrated in FIG. 1, in a case where the separation portion 4P2 is provided to continuously surround the semiconductor chip CHP1, the rigidity of the separation portion 4P2 itself is improved. Therefore, as illustrated in FIG. 1, it is particularly preferable that the separation portion 4P2 is provided to continuously surround the semiconductor chip CHP1.

In the example illustrated in FIG. 1, the separation portion 4P2 of the stiffener ring 4 is located between the semiconductor chip CHP1 and the adherend portion 4P1 of the stiffener ring 4 in plan view. Focusing only on the point of enhancing the rigidity of the stiffener ring 4, an embodiment in which the separation portion 4P2 is connected to the outer peripheral side of the adherend portion 4P1 in plan view is conceivable. However, from the viewpoint of curbing the warpage deformation of the wiring substrate SUB1 as described above, the adherend portion 4P1 of the stiffener ring 4 is preferably arranged along the peripheral edge portion of the upper surface 2t to which the largest stress is applied. Therefore, as illustrated in FIG. 1, the separation portion 4P2 of the stiffener ring 4 is preferably located between the semiconductor chip CHP1 and the adherend portion 4P1 of the stiffener ring 4 in plan view.

As illustrated in FIG. 1, in the case of the present embodiment, the outer edge of the stiffener ring has an octagonal shape in plan view. Specifically, in plan view, the outer edge of the adherend portion 4P1 of the stiffener ring 4 has four main sides 4ms and four corner sides 4cs continuous with two of the four main sides 4ms. The four main sides 4ms include a main side 4ms1 and a main side 4ms2 extending in the X direction, and a main side 4ms3 and a main side 4ms4 extending in the Y direction intersecting the X direction. Each of the four corner sides 4cs forms a straight line extending in a direction intersecting the X direction and the Y direction.

The shape of the stiffener ring 4 illustrated in FIG. 1 can be expressed as follows. That is, the adherend portion 4P1 of the stiffener ring has a shape in which corners where the four main sides 4ms intersect are chamfered. In addition to the C shape illustrated in FIG. 1, an R shape may be obtained through R-chamfering. Although not illustrated, in the case of R-chamfering, each of the four corner sides 4cs forms a curve extending in a direction intersecting the X direction and the Y direction.

As a modification example of the present embodiment, the outer edge of the stiffener ring 4 may have a quadrangular shape. However, from the following viewpoint, it is preferable that the corner has a chamfered shape as illustrated in FIG. 1. As illustrated in FIG. 1, an alignment mark AM is formed on the upper surface 2t of the wiring substrate SUB1. The alignment mark AM is arranged outside the stiffener ring 4 in plan view. Specifically, the alignment mark AM is arranged between one of the four corner sides 4cs of the stiffener ring 4 and one of the four corners (corner 2c4 in FIG. 1) of the upper surface 2t of the wiring substrate SUB1 in plan view.

The alignment mark AM is a mark for alignment used in a step of mounting a semiconductor chip on the wiring substrate SUB1, a step of mounting the electronic component CD1, a step of mounting the stiffener ring 4, or the like. The alignment mark AM may be used in a case where the heat dissipation member illustrated in FIG. 5 is mounted. Thus, the alignment mark AM is required to be arranged at a position with good visibility and to have high accuracy of alignment with the alignment mark AM as a reference. In consideration of these matters, it is preferable that the alignment mark AM is arranged as close as possible to the outer edge of the upper surface 2t in the upper surface 2t of the wiring substrate SUB1.

On the other hand, as described above, the stress contributing to the warpage deformation of the wiring substrate SUB1 is strongly applied to the outer edge portion of the wiring substrate SUB1. Therefore, the stiffener ring 4 is preferably arranged at a position close to the outer edge of the upper surface 2t. As illustrated in FIG. 1, in the case of the present embodiment, the outer edge of the stiffener ring 4 has four corner sides 4cs. Therefore, the alignment mark AM can be arranged at any location between the four corners of the upper surface 2t of the wiring substrate SUB1 and the four corner sides 4cs of the stiffener ring 4. That is, each of the stiffener ring 4 and the alignment mark AM can be arranged near the outer edge of the upper surface 2t. Since the alignment mark AM is arranged outside the stiffener ring 4, even if the stiffener ring 4 is mounted, the alignment mark AM can be visually recognized.

### Modification Example 1 of Stiffener Ring

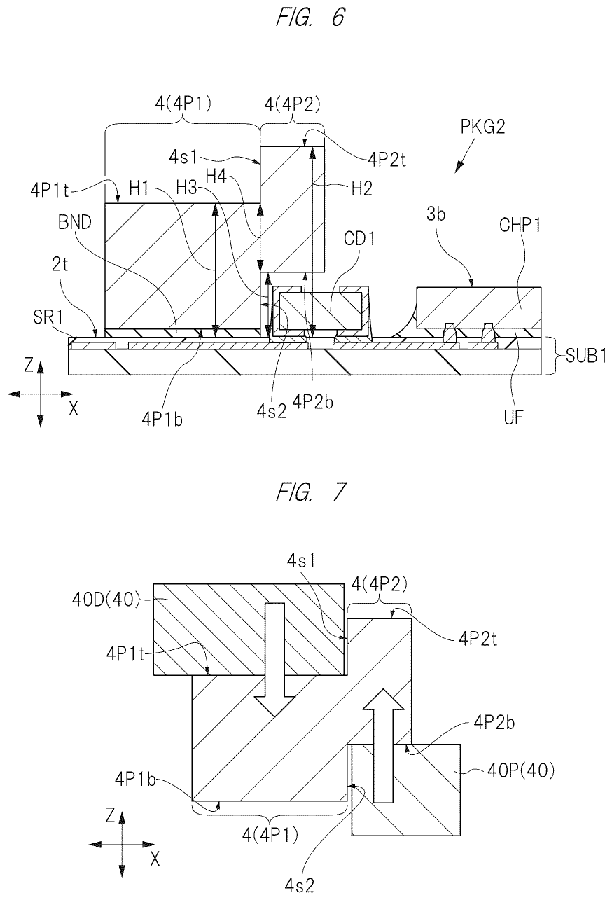

Next, a modification example of the semiconductor device described with reference to FIGS. 1 to 5 will be described. FIG. 6 is an enlarged cross-sectional view illustrating a periphery of a part of a stiffener ring which is a modification example of the stiffener ring in FIG. 4. FIG. 7 is an enlarged cross-sectional view schematically illustrating a state in which the stiffener ring illustrated in FIG. 6 is formed through half punching.

In the case of the example illustrated in FIG. 4, the upper surface 4P1t of the adherend portion 4P1 and the upper surface 4P2t of the separation portion 4P2 are at the same height with the upper surface 2t of the wiring substrate SUB1 as a reference surface. Such a shape is manufactured by using a method such as etching as follows.

First, a plate-shaped member (metal plate) having a constant thickness is prepared. Next, a mask is formed on one surface (a surface corresponding to the lower surface 4P1b in FIG. 4) of the member (metal plate). Next, an opening is formed in a part of the mask (a portion covering the separation portion 4P2 in FIG. 4). Next, a half etching process is performed to form a surface corresponding to the lower surface 4P2b illustrated in FIG. 4. Next, a through-hole is formed at the center of the stiffener ring 4. As a method of forming the through-hole, a method of performing an etching process or a method of mechanically forming a through-hole through punching may be selected.

In the case of the above manufacturing method, it is necessary to form a mask, form an opening of the mask, and the like, and thus work is complicated. From the viewpoint of improving the manufacturing efficiency of the stiffener ring 4 (in other words, the manufacturing efficiency of the semiconductor device), it is preferable that the stiffener ring 4 can be formed through mechanical processing. Therefore, a modification example of the stiffener ring 4 that can be formed through mechanical processing will be described below. In the following description, since a through-hole formed at the center of the stiffener ring 4 can be formed through general punching, the description by illustration will be omitted.

The adherend portion 4P1 of the stiffener ring 4 included in a semiconductor device PKG2 illustrated in FIG. 6 has a lower surface 4P1b facing the upper surface 2t of the wiring substrate and an upper surface 4P1t located on the opposite side to the lower surface 4P1b. A separation portion 4P2 of the stiffener ring 4 has a lower surface 4P2b facing the upper surface 2t of the wiring substrate and an upper surface 4P2t located on the opposite side to the lower surface 4P2b. This point is similar to the semiconductor device PKG1 illustrated in FIG. 4. In the case of the semiconductor device PKG2 illustrated in FIG. 6, a height difference H2 between the upper surface 2t and the upper surface 4P2t is larger than a height difference H1 between the upper surface 2t and the upper surface 4P1t. In this respect, the semiconductor device PKG2 illustrated in FIG. 6 is different from the semiconductor device PKG1 illustrated in FIG. 4.

The stiffener ring 4 illustrated in FIG. 6 is formed through mechanical processing (half punching), and is thus different from the stiffener ring 4 illustrated in FIG. 4 in the following points. That is, as illustrated in FIG. 6, the thickness of the adherend portion 4P1 is equal to the thickness of the separation portion 4P2.

The structure illustrated in FIG. 6 can be expressed as follows. That is, the stiffener ring 4 illustrated in FIG. 6 has a side surface 4s1 continuous with each of the upper surface 4P1t and the upper surface 4P2t, and a side surface 4s2 continuous with each of the lower surface 4P1b and the lower surface 4P2b. Each of the upper surface 4P1t, the upper surface 4P2t, the lower surface 4P1b, and the lower surface 4P2b is parallel to the upper surface 2t. Each of the side surface 4s1 and the side surface 4s2 is orthogonal to the upper surface 4P1t, the upper surface 4P2t, the lower surface 4P1b, and the lower surface 4P2b.

The stiffener ring 4 illustrated in FIG. 6 is formed by performing half punching using a punching machine 40 illustrated in FIG. 7. The half punching is a type of punching using a punch 40P and a die 40D, and is a processing method in which a member (metal plate) is not completely cut and is sheared partway (for example, up to about half the thickness of the member (metal plate)).

As illustrated in FIG. 7, the punching machine 40 used for forming the stiffener ring 4 through half punching includes the punch 40P and the die 40D. The punch 40P selectively contacts the lower surface 4P2b of the spaced portion 4P2 of the stiffener ring 4, and the die 40D selectively contacts the upper surface 4P1t of the adherend portion 4P1 of the stiffener ring 4. In this state, as illustrated in FIG. 7, the punch 40P is pushed upward. In the example illustrated in FIG. 7, the punch 40P moves upward and the die 40D moves downward, but one of the punch 40P and the die 40D may be fixed.

In a case where punching is performed as illustrated in FIG. 7, a part of the member (metal plate) is sheared halfway, and the adherend portion 4P1 and the separation portion 4P2 are formed. Each of the side surface 4s1 and the side surface 4s2 formed at this time is a shear surface. The side surface 4s1 is continuous to be orthogonal to each of the upper surface 4P1t and the upper surface 4P2t. The side surface 4s2 is continuous to be orthogonal to each of the lower surface 4P1b and the lower surface 4P2b.

In the case of the stiffener ring 4 formed through half punching, the adherend portion 4P1 and the separation portion 4P2 are directly connected. Therefore, as illustrated in FIG. 6, even in a case where the electronic component CD1 is arranged near the side surface 4s2, the stiffener ring 4 and the electronic component CD1 are less likely to come into contact with each other. In other words, the electronic component CD1 can be arranged near the side surface 4s2. In this case, the width of the adherend portion 4P1 can be increased in the X direction illustrated in FIG. 6.

However, in the case of the example illustrated in FIG. 6, from the viewpoint of securing the strength of the stiffener ring 4, it is necessary to increase the thickness of a boundary portion between the adherend portion 4P1 and the separation portion 4P2 to some extent. For example, in the example illustrated in FIG. 6, a height difference H3 between the upper surface 2t and the lower surface 4P2b is equal to or less than a height difference H4 between the upper surface 4P1t and the lower surface 4P2b. As described above, in order to secure a space for disposing the electronic component CD1 between the separation portion 4P2 and the wiring substrate SUB1 while increasing the thickness of the boundary portion between the adherend portion 4P1 and the separation portion 4P2 to some extent, it is necessary to increase the thicknesses of the adherend portion 4P1 and the separation portion 4P2.

The semiconductor device PKG2 illustrated in FIG. 6 is similar to the semiconductor device PKG1 described with reference to FIGS. 1 to 5 except for the above-described differences. Therefore, redundant description will be omitted.

### Modification Example 2 of Stiffener Ring

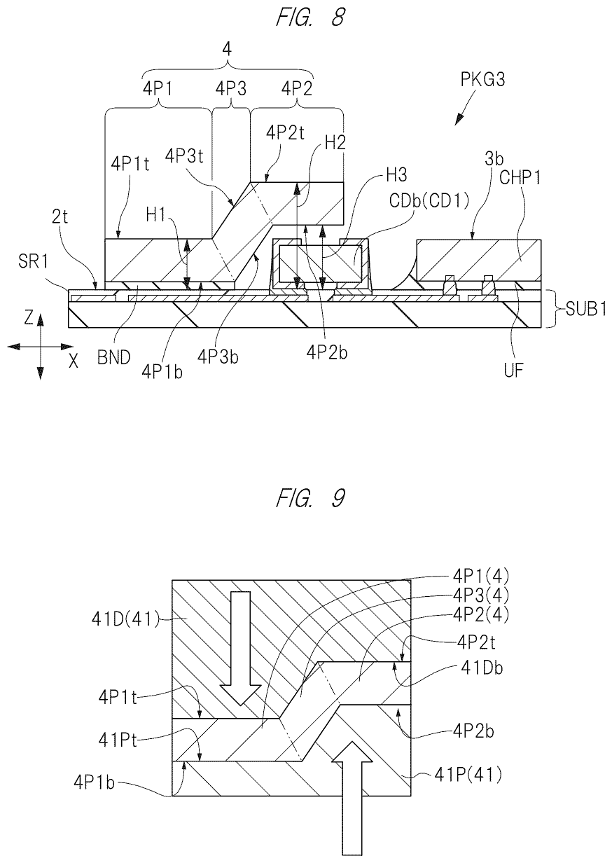

Next, a modification example of the semiconductor device described with reference to FIGS. 1 to 5 will be described. FIG. 8 is an enlarged cross-sectional view illustrating a periphery of a portion of a stiffener ring which is another modification example of the stiffener ring in FIG. 4. FIG. 9 is an enlarged cross-sectional view schematically illustrating a state in which the stiffener ring illustrated in FIG. 8 is formed through drawing.

The adherend portion 4P1 of the stiffener ring 4 included in a semiconductor device PKG3 illustrated in FIG. 8 has a lower surface 4P1b facing the upper surface 2t of the wiring substrate and an upper surface 4P1t located on the opposite side to the lower surface 4P1b. The separation portion 4P2 of the stiffener ring 4 has a lower surface 4P2b facing the upper surface 2t of the wiring substrate and an upper surface 4P2t located on the opposite side to the lower surface 4P2b. This point is similar to the semiconductor device PKG1 illustrated in FIG. 4 and the semiconductor device PKG2 illustrated in FIG. 6.

In the case of the semiconductor device PKG3 illustrated in FIG. 8, the height difference H2 between the upper surface 2t and the upper surface 4P2t is larger than the height difference H1 between the upper surface 2t and the upper surface 4P1t. Since the stiffener ring 4 illustrated in FIG. 8 is formed through mechanical processing (drawing), the thickness of the adherend portion 4P1 is equal to the thickness of the separation portion 4P2. These points are similar to the semiconductor device PKG2 illustrated in FIG. 6, but are different from the semiconductor device PKG1 illustrated in FIG. 4.

The stiffener ring 4 illustrated in FIG. 8 is formed through drawing using a pressing machine 41 illustrated in FIG. 9. The drawing is a type of pressing, and is a processing method in which a member (metal plate) is arranged between a punch 41P and a die 41D, which are molds, and then the punch 41P and the die 41D are brought close to each other to plastically deform the member.

As illustrated in FIG. 9, the pressing machine 41 used to form the stiffener ring 4 through drawing includes the punch 41P and the die 41D. The punch 41P is arranged on the lower surface (for example, the lower surface 4P1b) side of the metal plate, and the die 41D is arranged on the upper surface (for example, upper surface 4P1t) side of the metal plate. Each of the punch 41P and the die 41D is a mold for molding. In a case where a pressing surface 41Pt of the punch 41P and a pressing surface 41Db of the die 41D are combined, the metal plate sandwiched between the punch 41P and the die 41D is pressed to be formed into the shape of the stiffener ring 4. In the example illustrated in FIG. 9, the punch 41P moves upward and the die 41D moves downward, but one of the punch 41P and the die 41D may be fixed.

In a case where the stiffener ring 4 is formed through drawing, the obtained stiffener ring 4 has the following features. As illustrated in FIG. 8, the stiffener ring 4 further includes a connection portion 4P3 arranged between the adherend portion 4P1 and the separation portion 4P2 and connected to each of the adherend portion 4P1 and the separation portion 4P2. The connection portion 4P3 of the stiffener ring 4 has an upper surface 4P3t continuous with each of the upper surface 4P1t and the upper surface 4P2t, and a lower surface 4P3b continuous with each of the lower surface 4P1b and the lower surface 4P2b.

Unlike punching (half punching) described with reference to FIG. 7, drawing is a method of molding a metal plate by deforming the metal plate instead of shearing the metal plate. Therefore, the connection portion 4P3 is formed between the adherend portion 4P1 and the separation portion 4P2.

Incidentally, in order to make the lower surface 4P2b of the separation portion 4P2 higher than the lower surface 4P1b of the adherend portion 4P1 with the upper surface 2t of the wiring substrate SUB1 as a reference surface, the connection portion 4P3 needs to be inclined. In order to make the width of the adherend portion 4P1 in the X direction as large as possible, the inclination angle of the connection portion 4P3 is preferably large (an angle close to 90 degrees). However, as the inclination angle of the connection portion 4P3 becomes larger, the distortion applied to the stiffener ring 4 due to the drawing becomes larger.

In the example illustrated in FIG. 8, each of the upper surface 4P1t, the upper surface 4P2t, the lower surface 4P1b, and the lower surface 4P2b of the stiffener ring 4 is parallel to the upper surface 2t. Each of the upper surface 4P3t and the lower surface 4P3b intersects all of the upper surface 4P1t, the upper surface 4P2t, the lower surface 4P1b, and the lower surface 4P2b at an angle not orthogonal to each other. In other words, the inclination angle of the connection portion 4P3 is less than 90 degrees. In this case, the distortion applied to the stiffener ring 4 can be reduced.

Focusing on the thickness of the stiffener ring 4 or the height of the separation portion 4P2, the stiffener ring 4 formed through drawing has the following structural features.

In the case of the half punching described with reference to FIG. 7, since the metal plate is sheared, there is a restriction on the relationship between the thickness of the metal plate and the height of the separation portion 4P2. That is, a height difference between the lower surface 4P2b of the separation portion 4P2 and the lower surface 4P1b of the adherend portion 4P1 illustrated in FIG. 6 is preferably about half or less of the thickness of the metal plate. Therefore, if it is necessary to increase the value of the height difference H3 according to the height of the electronic component CD1 illustrated in FIG. 6, it is necessary to increase the plate thickness (that is, the thickness of the adherend portion 4P1 and the thickness of the separation portion 4P2) of the metal plate accordingly.

On the other hand, in a case where the stiffener ring 4 is molded through drawing, the above restriction is not put on the relationship between the thickness of the metal plate and the height of the separation portion 4P2. Therefore, the plate thickness (that is, the thickness of the adherend portion 4P1 and the thickness of the separation portion 4P2 illustrated in FIG. 8) of the metal plate can be reduced within a range in which the rigidity of the stiffener ring 4 can be obtained. The height difference H3 between the upper surface 2t and the lower surface 4P2b illustrated in FIG. 8 can be freely set according to the height of the electronic component CD1 regardless of the thickness of the metal plate.

Therefore, for example, in the example illustrated in FIG. 8, the height difference H3 between the upper surface 2t and the lower surface 4P2b is equal to or larger than the thickness of the adherend portion 4P1. As described with reference to FIG. 5, in a case where the heat dissipation member HS or the like is mounted on the back surface 3b of the semiconductor chip CHP1, the thickness of the stiffener ring 4 is preferably small from the viewpoint of preventing interference with the stiffener ring 4. In the case of the present modification example, the thickness of the stiffener ring 4 can be reduced within a range in which necessary rigidity can be secured, which is preferable.

The semiconductor device PKG3 illustrated in FIG. 8 is similar to the semiconductor device PKG1 described with reference to FIGS. 1 to 5 or the semiconductor device PKG2 described with reference to FIG. 6 except for the above-described differences. Therefore, redundant description will be omitted.

### Method of Manufacturing Semiconductor Device

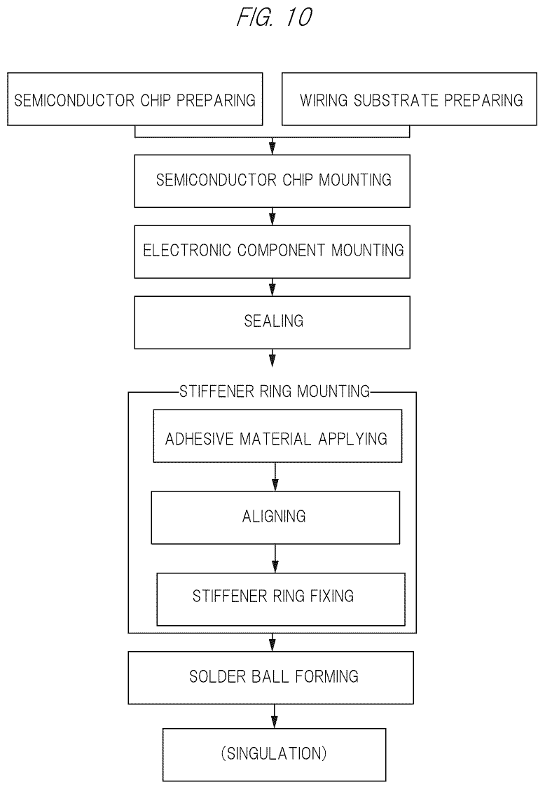

Next, a method of manufacturing a semiconductor device will be described. Hereinafter, as a representative example, a method of manufacturing the semiconductor device PKG1 described with reference to FIGS. 1 to 4 will be mainly described, and thereafter, only differences will be described in principle regarding modification examples. FIG. 10 is an explanatory diagram illustrating an example of a flow of an assembly step of a semiconductor device according to an embodiment.

### Wiring Substrate Preparing Step

As a wiring substrate preparing step illustrated in FIG. 10, the wiring substrate SUB1 illustrated in FIG. 3 is prepared. In the wiring substrate SUB1 prepared in this step, each member of the wiring substrate SUB1 described with reference to FIGS. 1 to 3 is formed. However, at the stage of this step, the wiring substrate SUB1 before each of the semiconductor chip CHP1, the electronic component CD1, and the stiffener ring 4 is mounted on the wiring substrate SUB1 is prepared.

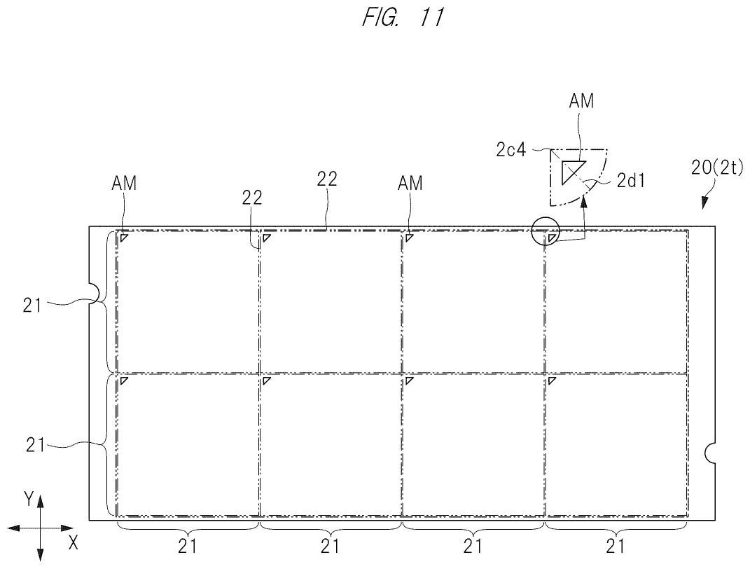

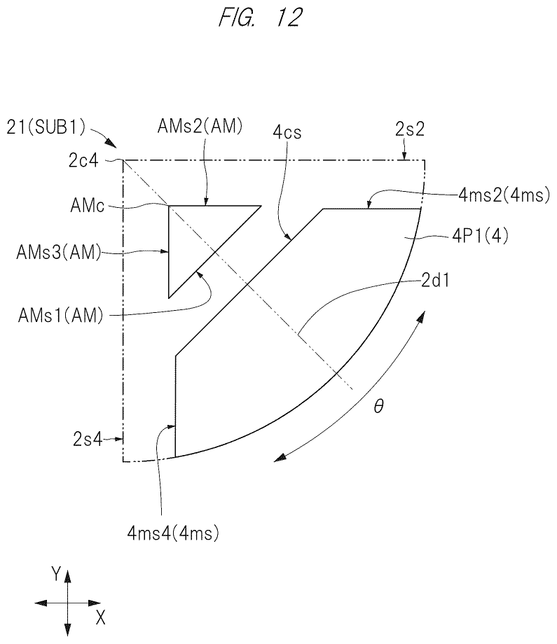

Incidentally, in the wiring substrate preparing step, as illustrated in FIG. 11, there is a case where a wiring substrate 20, which is a so-called multi-piece substrate provided with a plurality of device regions 21, is prepared. An upper surface 2t of the wiring substrate 20 has a plurality of device regions 21 and a dicing region 22 surrounding the periphery of each of the plurality of device regions 21. FIG. 11 is a plan view illustrating a modification example of the wiring substrate prepared in the wiring substrate preparing step illustrated in FIG. 10. In the following description, the wiring substrate may be referred to as the wiring substrate SUB1 with reference to any one of FIGS. 1 to 3. In a case where a multi-piece substrate is used, in the following description, the term “wiring substrate SUB1” can be applied by replacing it with the device region 21 of the wiring substrate 20.

The alignment mark AM described with reference to FIG. 1 is formed in each of the plurality of device regions 21. The alignment mark AM is arranged in the vicinity of one of the corners (for example, a corner corresponding to the corner 2c4 illustrated in FIG. 1) of the plurality of device regions 21. In the example illustrated in FIG. 1, the alignment mark AM is a right-angled isosceles triangle having a right-angled vertex (a vertex AMc illustrated in FIG. 12 that will be described later) at a position overlapping a diagonal line 2d1. The diagonal line 2d1 overlaps the midpoint of the base of the right-angled isosceles triangle (the side not including the vertex of the right angle: a base AMs1 illustrated in FIG. 12 that will be described later).

### Semiconductor Chip Preparing Step

As the semiconductor chip preparing step illustrated in FIG. 10, the semiconductor chip CHP1 illustrated in FIGS. 1, 3, and 4 is prepared. Since a structure of the semiconductor chip CHP1 is as described above, redundant description will be omitted.

### Semiconductor Chip Mounting Step

Next, as a semiconductor chip mounting step illustrated in FIG. 10, the semiconductor chip CHP1 is mounted on the upper surface 2t of the wiring substrate SUB1 as illustrated in FIG. 3. The semiconductor chip CHP1 is mounted on each of the plurality of device regions 21 illustrated in FIG. 11. In the semiconductor chip mounting step, the semiconductor chip CHP1 is mounted on the wiring substrate SUB1 such that the front surface 3t faces the upper surface 2t of the wiring substrate SUB1. The plurality of electrodes 3PD of the semiconductor chip CHP1 is respectively arranged at positions facing the plurality of pads 2PD of the wiring substrate SUB1. After the semiconductor chip CHP1 is arranged on the wiring substrate SUB1, a reflow process is performed, so that the plurality of electrodes 3PD and the plurality of pads 2PD is electrically connected via the projecting electrodes 3BP. Such a connection method is called a flip-chip connection method, and the semiconductor chip mounting step of the present embodiment is called a face-down mounting method in which the front surface 3t of the semiconductor chip CHP1 and the upper surface 2t of the wiring substrate SUB1 face each other.

### Electronic Component Mounting Step

Next, as an electronic component mounting step illustrated in FIG. 10, the electronic component CD1 is mounted on the upper surface 2t of the wiring substrate SUB1 as illustrated in FIG. 3. The electronic component CD1 is mounted in each of the plurality of device regions 21 illustrated in FIG. 11. In the electronic component mounting step, as described with reference to FIG. 4, the electronic component CD1 includes the plurality of electrodes CDe (two electrodes in FIG. 4) and the main body portion CDb connected to each of the plurality of electrodes CDe. In this step, a solder material is disposed on the plurality of terminals exposed from the insulating film SR1 on the upper surface 2t of the wiring substrate SUB1 illustrated in FIG. 4. Next, the electronic component CD1 is disposed on the upper surface 2t such that the plurality of electrodes CDe of the electronic component and the terminals of the wiring substrate SUB1 face each other with the solder material interposed therebetween. Thereafter, performing the reflow process allows the electrode CDe and the terminal of the wiring substrate SUB1 to be electrically connected via the solder material.

In FIG. 10, the semiconductor chip mounting step and the electronic component mounting step are distinguished from each other, but the reflow process included in each step may be collectively performed.

### Sealing Step

Next, as a sealing step illustrated in FIG. 10, as illustrated in FIG. 4, the underfill resin UF is supplied between the semiconductor chip CHP1 and the wiring substrate SUB1, and the plurality of projecting electrodes 3BP are sealed while being insulated from each other.

### Stiffener Ring Mounting Step

Next, as a stiffener ring mounting step illustrated in FIG. 10, the stiffener ring 4 is mounted on the upper surface 2t of the wiring substrate SUB1 as illustrated in FIGS. 1 and 3. As illustrated in FIG. 10, the stiffener ring mounting step includes an adhesive material applying step, an alignment step, and a stiffener ring fixing step.

In the adhesive material applying step illustrated in FIG. 10, an adhesive material is applied to a planned region where the stiffener ring 4 (see FIG. 1) is to be mounted, specifically, a planned region facing the lower surface 4P1b of the adherend portion 4P1 illustrated in FIG. 4. The adhesive material is, for example, a paste agent containing a thermosetting resin component, and is cured to form the adhesive layer BND illustrated in FIG. 4.

In this step, in the upper surface 2t of the wiring substrate SUB1, the adhesive material is applied to the entire planned region facing the lower surface 4P1b of the adherend portion 4P1 illustrated in FIG. 4. Alternatively, in this step, in the upper surface 2t of the wiring substrate SUB1, the adhesive material may be applied to a part (a plurality of locations) of a planned region facing the lower surface 4P1b of the adherend portion 4P1 illustrated in FIG. 4.

Next, in the alignment step illustrated in FIG. 10, a position and an orientation of the stiffener ring illustrated in FIG. 1 are adjusted with reference to the position of the alignment mark AM illustrated in FIG. 11. FIG. 12 is an enlarged plan view illustrating a state in which the positional relationship between the alignment mark and the stiffener ring is adjusted in the alignment step illustrated in FIG. 10.

As described with reference to FIGS. 1 to 4, in a case where the separation portion 4P2 of the stiffener ring 4 is mounted to cover the electronic component CD1, positional accuracy in mounting the stiffener ring 4 is important. In the X-Y plane illustrated in FIG. 12, in a case where the deviation in the angle of the stiffener ring 4 in the θ direction (hereinafter, referred to as a deviation in the θ direction) is large, a part of the adherend portion 4P1 of the stiffener ring 4 may come into contact with the electronic component CD1.

In the case of the present embodiment, as described with reference to FIG. 1, the outer edge of the adherend portion 4P1 of the stiffener ring 4 has the four main sides 4ms and the four corner sides 4cs continuous with two of the four main sides 4ms. The four main sides 4ms include the main side 4ms1 and the main side 4ms2 extending in the X direction, and the main side 4ms3 and the main side 4ms4 extending in the Y direction intersecting the X direction. Each of the four corner sides 4cs forms a straight line (or a curve) extending in a direction intersecting each of the X direction and the Y direction.

In the alignment step, the alignment accuracy can be improved using the outer diameter shape of the stiffener ring 4 described above. For example, in the present embodiment, in the alignment step, the position of the alignment mark AM and the position of one of the four corner sides 4cs (see FIG. 1) of the stiffener ring 4 are acquired by an image sensor (not illustrated).

Next, the position of the stiffener ring 4 and the position of the wiring substrate SUB1 are adjusted with reference to the position of the alignment mark AM and the position of one of the four corner sides 4cs of the stiffener ring 4. In this case, as illustrated in FIG. 12, for example, the alignment is performed such that the base AMs1 of the alignment mark AM and the corner side 4cs of the stiffener ring 4 are parallel to each other. Alternatively, the alignment is performed such that a side AMs2 of the alignment mark AM and the main side 4ms2 of the stiffener ring 4 are arranged on a straight line, and a side AMs3 of the alignment mark AM and the main side 4ms4 of the stiffener ring 4 are arranged on a straight line.

In this case, a deviation in the stiffener ring 4 in the θ direction can be suppressed. As illustrated in FIG. 12, it has already been described that alignment as in the present embodiment can be realized by disposing the alignment mark AM outside the stiffener ring 4.

According to the present embodiment, since the alignment of the stiffener ring 4 can be performed with high accuracy, the contact between the electronic component CD1 and the stiffener ring 4 can be prevented even in a case where the separation distance between the electronic component CD1 and the adherend portion 4P1 of the stiffener ring 4 illustrated in FIG. 4 is small in design. If the separation distance between the electronic component CD1 illustrated in FIG. 4 and the adherend portion 4P1 of the stiffener ring 4 can be reduced, the width of the adherend portion 4P1 in the X direction illustrated in FIG. 4 can be increased. Consequently, the adhesion area between the adherend portion 4P1 and the wiring substrate SUB1 (in other words, the area of the lower surface 4P1b of the adherend portion 4P1) can be increased, so that the adhesion strength between the stiffener ring 4 and the wiring substrate SUB1 can be improved.

Next, in the stiffener ring fixing step illustrated in FIG. 10, the aligned stiffener ring 4 is pressed toward the wiring substrate SUB1. The adhesive material applied on the upper surface 2t is sandwiched between the lower surface of the stiffener ring 4 and the upper surface 2t of the wiring substrate SUB1 and is pushed and spread around. As a result, a shape of the adhesive material becomes the shape of the adhesive layer BND illustrated in FIG. 4.

Subsequently, the adhesive material interposed between the stiffener ring 4 (see FIG. 3) and the wiring substrate SUB1 (see FIG. 3) is cured to form the adhesive layer BND (see FIG. 3). This step fixes the stiffener ring 4 onto the wiring substrate SUB1.

### Solder Ball Forming Step

Next, as a solder ball forming step illustrated in FIG. 10, as illustrated in FIG. 2, a plurality of solder balls SB is formed on the lower surface 2b of the wiring substrate SUB1.

In this step, the plurality of solder balls SB (see FIGS. 2 and 4) is bonded to the plurality of lands 2LD formed on the lower surface of the wiring substrate SUB1 illustrated in FIG. 3. After a solder material is disposed on each of the plurality of lands 2LD exposed on the lower surface of the wiring substrate SUB1, a reflow process is performed. As the solder material, for example, a solder ball may be used. The solder ball is heated to a temperature equal to or higher than the melting point of the solder ball, and then cooled to be bonded to the land 2LD. In order to activate the surface of the solder ball, a reflow process may be performed in a state in which the solder ball is in contact with a flux. Alternatively, as a modification example of this step, a solder material containing a solder component and a flux component called a solder paste may be applied. In either method, the solder material is formed in a ball shape on the land 2LD by the surface tension of the solder component, so that a plurality of solder balls SB illustrated in FIG. 2 can be obtained.

The flux component used for activating the surface of the solder material may remain as a residue around the solder ball SB due to the reflow process. In this case, although not illustrated in FIG. 10, it is preferable to add a washing step after the solder ball forming step to remove the residue of the flux component.

### Singulation Step

In a case where the wiring substrate 20 described with reference to FIG. 11 is used, as illustrated in FIG. 10, a singulation step is performed after the solder ball forming step. In the singulation step, the wiring substrate 20 is cut along the dicing region 22 illustrated in FIG. 11, and each of the plurality of device regions 21 is segmented. A cutting method is not particularly limited, and for example, a method of cutting the wiring substrate 20 through cutting using a dicing blade (not illustrated) can be exemplified. In the wiring substrate preparing step illustrated in FIG. 10, in a case where the wiring substrate SUB1 illustrated in FIGS. 1 to 6 is prepared, the singulation step can be omitted. This is because the wiring substrate SUB1 illustrated in FIGS. 1 to 6 corresponds to one device region 21 illustrated in FIG. 11.

In the foregoing, the invention made by the inventors of the present application has been concretely described on the basis of the embodiments. However, it is needless to say that the present invention is not limited to the foregoing embodiments, and various modifications and alterations can be made within the scope of the present invention.

For example, as a modification example of the stiffener ring 4 illustrated in FIG. 3, the thickness of the stiffener ring 4 may be smaller than not only the thickness T2 of the wiring substrate SUB1 but also the thickness of the core insulating layer 2CR configuring the wiring substrate SUB1. However, in order to more reliably prevent the warpage deformation of the wiring substrate SUB1, it is preferable to use a stiffener ring of which a rigidity is improved by increasing the thickness of the plurality of adhesive layers BND in addition to disposing the plurality of adhesive layers BND at appropriate positions.

What is claimed is:

1. A semiconductor device comprising:
a wiring substrate having a first upper surface and a first lower surface opposite the first upper surface;
a semiconductor chip mounted on the first upper surface of the wiring substrate;
an electronic component mounted on the first upper surface of the wiring substrate; and
a stiffener ring fixed to the first upper surface of the wiring substrate,
wherein the stiffener ring includes:
a first portion arranged to continuously surround a periphery of the semiconductor chip in plan view and adhering to the first upper surface of the wiring substrate, and
a second portion connected to the first portion and arranged at a position spaced away from the first upper surface of the wiring substrate, and
wherein the second portion of the stiffener ring partially overlaps the electronic component.

2. The semiconductor device according to claim 1,
wherein the second portion of the stiffener ring is located between the semiconductor chip and the first portion of the stiffener ring in plan view.

3. The semiconductor device according to claim 2,
wherein the second portion of the stiffener ring is arranged to continuously surround the periphery of the semiconductor chip in plan view.

4. The semiconductor device according to claim 3,
wherein the first portion of the stiffener ring has a second lower surface facing the first upper surface of the wiring substrate and a second upper surface opposite the second lower surface,
wherein the second portion of the stiffener ring has a third lower surface facing the first upper surface of the wiring substrate and a third upper surface opposite the third lower surface,
wherein a height difference between the first upper surface and the third upper surface is equal to a height difference between the first upper surface and the second upper surface, and
wherein the first portion and the second portion are directly connected to each other.

5. The semiconductor device according to claim 3,
wherein the first portion of the stiffener ring has a second lower surface facing the first upper surface of the wiring substrate and a second upper surface opposite the second lower surface,
wherein the second portion of the stiffener ring has a third lower surface facing the first upper surface of the wiring substrate and a third upper surface opposite the third lower surface, and
wherein a height difference between the first upper surface and the third upper surface is larger than a height difference between the first upper surface and the second upper surface.

6. The semiconductor device according to claim 5,
wherein a thickness of the first portion is equal to a thickness of the second portion.

7. The semiconductor device according to claim 6,
wherein the first portion and the second portion are directly connected to each other, and
wherein a height difference between the first upper surface and the third lower surface is equal to or less than a height difference between the second upper surface and the third lower surface.

8. The semiconductor device according to claim 5,
wherein the stiffener ring includes:
a first side surface continuous with each of the second upper surface and the third upper surface, and
a second side surface continuous with each of the second lower surface and the third lower surface,
wherein each of the second upper surface, the third upper surface, the second lower surface, and the third lower surface is parallel to the first upper surface, and
wherein each of the first side surface and the second side surface is orthogonal to the second upper surface, the third upper surface, the second lower surface, and the third lower surface.

9. The semiconductor device according to claim 5,
wherein the stiffener ring further includes a third portion disposed between the first portion and the second portion and connected to each of the first portion and the second portion.

10. The semiconductor device according to claim 9,
wherein the third portion of the stiffener ring includes:
a fourth upper surface continuous with each of the second upper surface and the third upper surface, and
a fourth lower surface continuous with each of the second lower surface and the third lower surface,
wherein each of the second upper surface, the third upper surface, the second lower surface, and the third lower surface is parallel to the first upper surface, and
wherein each of the fourth upper surface and the fourth lower surface intersects the second upper surface, the third upper surface, the second lower surface, and the third lower surface at an angle not orthogonal to the second upper surface, the third upper surface, the second lower surface, and the third lower surface.

11. The semiconductor device according to claim 10,
wherein a height difference between the first upper surface and the third lower surface is equal to or more than a thickness of the first portion.

12. The semiconductor device according to claim 3,
wherein, in plan view, an outer edge of the first portion of the stiffener ring has four main sides and four corner sides continuous with two of the four main sides,
wherein the four main sides have:
a first main side and a second main side extending in a first direction, and
a third main side and a fourth main side extending in a second direction intersecting the first direction, and
wherein each of the four corner sides forms a straight line or a curved line extending in a direction intersecting the first direction and the second direction.

13. The semiconductor device according to claim 12, further comprising:
an alignment mark formed on the first upper surface of the wiring substrate,
wherein the alignment mark is arranged between an outer edge of the first upper surface of the wiring substrate and the stiffener ring in plan view.

14. A method of manufacturing a semiconductor device, comprising:
(a) preparing a wiring substrate including a first upper surface having a plurality of device regions and a dicing region surrounding a periphery of each of the plurality of device regions;
(b) mounting a semiconductor chip on the first upper surface of each of the plurality of device regions;
(c) mounting an electronic component on the first upper surface of each of the plurality of device regions; and
(d) after the (b) and the (c), mounting a stiffener ring on the first upper surface of each of the plurality of device regions,
wherein the stiffener ring mounted in the (d) has:
a frame shape in plan view and includes a first portion that adheres to the first upper surface in the (d); and
a second portion connected to the first portion and arranged at a position spaced away from the first upper surface in the (d), and
wherein, in the (d), the stiffener ring is mounted on the first upper surface of each of the plurality of device regions such that the second portion of the stiffener ring partially overlaps the electronic component.

15. The method of manufacturing a semiconductor device according to claim 14,
wherein, in the (d), the second portion of the stiffener ring is located between the semiconductor chip and the first portion of the stiffener ring in plan view and is disposed to continuously surround a periphery of the semiconductor chip in plan view,
wherein, in plan view, an outer edge of the first portion of the stiffener ring has four main sides and four corner sides continuous with two of the four main sides,
wherein the four main sides have
a first main side and a second main side extending in a first direction, and
a third main side and a fourth main side extending in a second direction intersecting the first direction, and
wherein each of the four corner sides forms a straight line or a curved line extending in a direction intersecting the first direction and the second direction.

16. The method of manufacturing a semiconductor device according to claim 15,
wherein the wiring substrate further includes an alignment mark formed in each of the plurality of device regions, and
wherein, in the (d), the stiffener ring is mounted on the first upper surface after adjusting a mounting position of the stiffener ring with reference to a position of the alignment mark and a position of one of the four corner sides of the stiffener ring.
